(19) United States
(12) Patent Application Publication
(10) Pub. No.: US 2026/0149241 A1
(43) Pub. Date: May 28, 2026

(54) SEMICONDUCTOR OPTICAL AMPLIFIER

(71) Applicant: SUMITOMO ELECTRIC INDUSTRIES, LTD., Osaka (JP)

(72) Inventor: Takehiko KIKUCHI, Osaka (JP)

(73) Assignee: SUMITOMO ELECTRIC INDUSTRIES, LTD., Osaka (JP)

(21) Appl. No.: 19/398,159

(22) Filed: Nov. 24, 2025

(30) Foreign Application Priority Data
Nov. 28, 2024 (JP) 2024-207691

(51) Int. Cl. H01S 5/50; H01S 5/10; H01S 5/22; H01S 5/343

(52) U.S. Cl. CPC H01S 5/50; H01S 5/1014; H01S 5/22; H01S 5/343

(57) ABSTRACT

A semiconductor optical amplifier includes a substrate including a silicon layer, and a gain section formed of a III-V compound semiconductor and having an optical gain, the gain section being bonded to the silicon layer. The silicon layer has a waveguide. The gain section has a mesa at a position overlapping the waveguide. The mesa protrudes in a direction away from the substrate and is located over the waveguide. In a portion of the waveguide overlapping the mesa, a portion of the waveguide close to an input end of the gain section has a smaller cross-sectional area, and a portion of the waveguide close to an output end of the gain section has a larger cross-sectional area.

### CROSS REFERENCE TO RELATED APPLICATIONS

This application claims priority based on Japanese Patent Application No. 2024-207691 filed on Nov. 28, 2024, and the entire contents of the Japanese patent application are incorporated herein by reference.

### TECHNICAL FIELD

The present disclosure relates to a semiconductor optical amplifier.

### BACKGROUND

A hybrid semiconductor optical device can be formed by bonding a gain region formed of a III-V compound semiconductor and having an optical gain to a substrate such as a silicon on insulator (SOI) substrate (silicon photonics) on which a waveguide is formed (for example, Non-patent literature 1: Cheung, et al. “Theory and Design Optimization of Energy-Efficient Hydrophobic Wafer-bonded III-V/Si Hybrid Semiconductor Optical Amplifiers” Journal of Lightwave Technology, Vol. 31, No. 24, pp. 4057-4066, Dec. 15, 2013).

### SUMMARY OF INVENTION

A semiconductor optical amplifier according to the present disclosure includes a substrate including a silicon layer, and a gain section formed of a III-V compound semiconductor and having an optical gain, the gain section being bonded to the silicon layer. The silicon layer has a waveguide. The gain section has a mesa at a position overlapping the waveguide. The mesa protrudes in a direction away from the substrate and is located over the waveguide. In a portion of the waveguide overlapping the mesa, a portion of the waveguide close to an input end of the gain section has a smaller cross-sectional area, and a portion of the waveguide close to an output end of the gain section has a larger cross-sectional area.

### BRIEF DESCRIPTION OF THE DRAWINGS

FIG. 1 is a plan view illustrating a semiconductor laser device according to a first embodiment.

FIG. 2A is a plan view illustrating an SOA.

FIG. 2B is a plan view illustrating a substrate of the SOA.

FIG. 3A is a cross-sectional view illustrating the SOA.

FIG. 3B is a cross-sectional view illustrating the SOA.

FIG. 3C is a cross-sectional view illustrating the SOA.

FIG. 4 is a diagram illustrating a light confinement factor.

FIG. 5A is a schematic view illustrating light distribution.

FIG. 5B is a schematic view illustrating light distribution.

FIG. 5C is a schematic view illustrating light distribution.

FIG. 6 is a diagram illustrating gain.

FIG. 7 is a plan view illustrating a portion of a waveguide according to a second embodiment.

FIG. 8 is a plan view illustrating a portion of a waveguide according to a third embodiment.

FIG. 9 is a plan view illustrating a substrate of an SOA according to a fourth embodiment.

### DETAILED DESCRIPTION

In a semiconductor optical amplifier, current is injected into a gain region to amplify light propagating through a waveguide. The intensity ratio (light amplification factor) between light input to the semiconductor optical amplifier and light output from the semiconductor optical amplifier is referred to as gain. In a general semiconductor optical amplifier, the gain decreases as the output increases. This is called gain saturation. By increasing a width of the gain region, the gain is less likely to saturate and energy efficiency increases. In the wide gain region, a high-order transverse mode is excited. Single-mode light propagates through the waveguide. Loss is occurred when light is coupled between the gain region and the waveguide. Thus, it is an object of the present disclosure to provide a semiconductor optical amplifier capable of obtaining a high gain and reducing loss.

### Description of Embodiments of Present Disclosure

The contents of the embodiments of the present disclosure will be listed and described first.
(1) A semiconductor optical amplifier according to an embodiment of the present disclosure includes a substrate including a silicon layer, and a gain section formed of a III-V compound semiconductor and having an optical gain, the gain section being bonded to the silicon layer. The silicon layer has a waveguide. The gain section has a mesa at a position overlapping the waveguide. The mesa protrudes in a direction away from the substrate and is located over the waveguide. In a portion of the waveguide overlapping the mesa, a portion of the waveguide close to an input end of the gain section has a smaller cross-sectional area, and a portion of the waveguide close to an output end of the gain section has a larger cross-sectional area. The cross-sectional area of the waveguide is increased, and thus the light confinement factor in the gain section is reduced. Since light is distributed not only in the III-V compound semiconductor having an optical gain but also in the waveguide of the silicon layer, the saturation of the gain can be prevented and a high gain can be obtained. Since the mesa of the gain section determines the mode shape, single-mode light propagates in the gain section and the waveguide. The loss of light can be reduced.
(2) In the above (1), in the portion of the waveguide overlapping the mesa, the portion of the waveguide close to the input end of the gain section may have a smaller width, and the portion of the waveguide close to the output end of the gain section may have a larger width. Since the waveguide has a large width, the cross-sectional area is also large. The saturation of the gain can be prevented.
(3) In the above (1) or (2), the width of the portion of the waveguide close to the output end of the gain section may be four or more times as large as the width of the portion of the waveguide close to the input end of the gain section. Since the waveguide has a large width, the cross-sectional area is also large. The saturation of the gain can be prevented.
(4) In any one of the above (1) to (3), the mesa may have a first tapered portion at each of an end portion close to the input end and an end portion close to the output end, and, in a portion of the waveguide located between two first tapered portions, a portion of the waveguide close to the input end of the gain section has a larger cross-sectional area, and a portion of the waveguide close to the output end of the gain section may have a smaller cross-sectional area. The light input from the input end is strongly confined in the gain section. Since the cross-sectional area of the waveguide increases in the portion close to the output end, the light confinement rate to the gain section decreases. The saturation of the gain can be prevented.
(5) In the above (4), the mesa may have a constant width along an extending direction of the waveguide between the two first tapered portions. The width of the mesa determines the mode shape. A high-order transverse mode is less likely to occur, and a single mode propagates. In the coupling of the gain section and the waveguide, the loss of light can be reduced.
(6) In the above (5), the mesa may have a width larger than the width of the portion of the waveguide close to the input end of the gain section and smaller than the width of the portion of the waveguide close to the output end of the gain section. At a position close to the input end, the light is transferred to the gain section. The width of the waveguide is large at a position close to the output end, and thus the light is also distributed in the waveguide. The saturation of the gain can be prevented.
(7) In any one of the above (1) to (6), the gain section may include a first semiconductor layer, an active layer, and a second semiconductor layer. The first semiconductor layer may be bonded to the substrate and have a first conductivity type. The active layer and the second semiconductor layer may be sequentially stacked over the first semiconductor layer. The second semiconductor layer may form the mesa and have a second conductivity type. Carriers can be selectively injected into the mesa. The light can be efficiently amplified.
(8) In the above (7), the first semiconductor layer may have two second tapered portions. One of the two second tapered portions may form a part of the input end. Another one of the two second tapered portions may form a part of the output end. The mesa may be located in a portion located between the two second tapered portions. In the portion located between the two second tapered portions, a portion of the waveguide close to the input end of the gain section may have a smaller cross-sectional area, and a portion of the waveguide close to the output end of the gain section may have a larger cross-sectional area. The light input from the input end is strongly confined in the gain section. Since the cross-sectional area of the waveguide increases in the portion close to the output end, the light confinement factor to the gain section decreases. The saturation of the gain can be prevented.
(9) In the above (1) to (8), the silicon layer may have a recessed portion, and the recessed portion may be located on each of two sides of the waveguide. The light can be concentrated around the waveguide to prevent the spreading of the mode. Light is transferred between the waveguide and the gain section.
(10) In the above (1) to (9), the waveguide may have a width that varies continuously or discontinuously along the extending direction of the waveguide. Since the waveguide has a large width near the output end of the gain section, the cross-sectional area is also large. The saturation of the gain can be prevented.

### Details of Embodiments of Present Disclosure

Specific examples of a semiconductor optical amplifier according to an embodiment of the present disclosure will be described below with reference to the drawings. The present disclosure is not limited to these examples, but is defined by the scope of the claims, and is intended to include all modifications within the meaning and scope equivalent to the scope of the claims.

### First Embodiment

### (Semiconductor Laser Device)

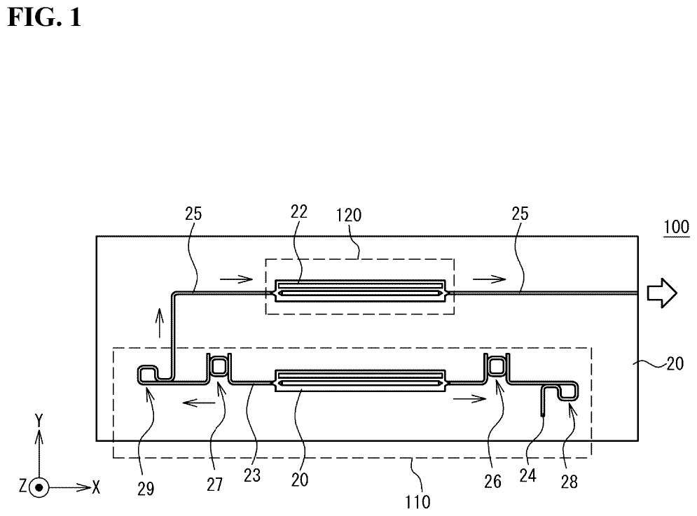

FIG. 1 is a plan view illustrating a semiconductor laser device 100 according to a first embodiment. The semiconductor laser device 100 is a device in which a wavelength tunable laser 110 and a semiconductor optical amplifier (SOA) 120 are integrated on one chip.

The semiconductor laser device 100 is a hybrid type element, and includes a substrate 10, a gain section 20, and a gain section 22. The substrate 10 includes a waveguide 23, a waveguide 24, and a waveguide 25. Two sides of the substrate 10 are parallel to an X-axis. The other two sides are parallel to a Y-axis. The upper surface of the substrate 10 is parallel to an XY plane. A Z-axis direction is a normal direction of the upper surface.

An annular waveguide is provided between the waveguide 23 and the waveguide 24. The annular waveguide, the waveguide 23, and the waveguide 24 are optically coupled to form a ring resonator 26. A ring waveguide having an annular shape is provided between the waveguide 23 and the waveguide 25. The annular waveguide, the waveguide 23, and the waveguide 25 are optically coupled to each other to form a ring resonator 27. The perimeter of the ring waveguide of the ring resonator 26 is different from the perimeter of the ring waveguide of the ring resonator 27.

The waveguide 24 is curved in a loop shape to form a loop mirror 28. A portion of the waveguide 25 between the ring resonator 27 and the gain section 22 is curved in a loop shape to form a loop mirror 29. The waveguide 25 has a portion extending from the loop mirror 29 in a Y-axis direction, a portion bent toward an X-axis direction, and a portion extending to the end portion of the substrate 10. The end portion of the waveguide 25 functions as an output port.

The wavelength tunable laser 110 includes the gain section 20, the waveguide 23, the ring resonator 26, the ring resonator 27, the loop mirror 28, and the loop mirror 29. The gain section 20 is bonded to the upper surface of the substrate 10. In a plan view, the gain section 20 overlaps the waveguide 23. The ring resonator 26, the ring resonator 27, the loop mirror 28, and the loop mirror 29 are separated from the gain section 20. Along the axis in which light is guided, the loop mirror 28, the ring resonator 26, the gain section 20, the ring resonator 27, and the loop mirror 29 are arranged in this order. The loop mirror 28, the ring resonator 26, the gain section 20, the ring resonator 27, and the loop mirror 29 may be arranged in order along the X-axis.

The SOA 120 has the gain section 22 and the waveguide 25. The gain section 22 is separated from the gain section 20 in the Y-axis direction. The gain section 22 may be separated from the gain section 20 in the Y-axis direction. The gain section 22 is bonded to a position of the substrate 10 overlapping the waveguide 25.

The gain section 20 and the gain section 22 are semiconductor elements formed of a III-V compound semiconductor and have an optical gain. The gain section 20 is evanescently coupled to the waveguide 23. The gain section 22 is evanescently coupled to the waveguide 25. Carriers is injected into the gain section 20, and thus the gain section 20 generates light. The light is transferred from the gain section 20 to the waveguide 23, and the light propagates in two directions. One of the two direction is a direction toward the loop mirror 28 and another of the two direction is a direction toward the loop mirror 29.

The light propagating through the waveguide 23 travels back and forth between the loop mirror 28 and the loop mirror 29. The light resonates in the ring resonator 26 and is reflected from the loop mirror 28. The light resonates in the ring resonator 27 and is reflected from the loop mirror 29. The light oscillates, for example, at a wavelength of 1550 nm by the vernier effect generated in the ring resonator 26 and the ring resonator 27. A part of the laser light propagates to the SOA 120 through the waveguide 25.

The light propagating through the waveguide 25 is input from one end (first end) of the gain section 22 and output from the other end (second end). Voltage is applied to the gain section 22. Stimulated emission occurs in the gain section 22, and light is amplified. The amplified light propagates through the waveguide 25 and is emitted from the output port.

In one example, the optical output power of the wavelength tunable laser is 3 dBm. The light amplification gain of the SOA 120 is 10 dB. The optical output power after amplification by the SOA 120 is 13 dBm.

### (SOA)

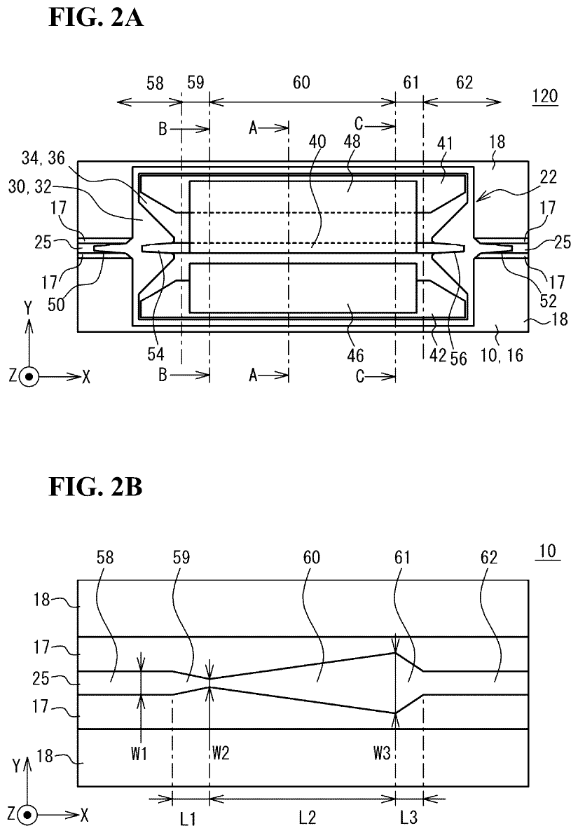

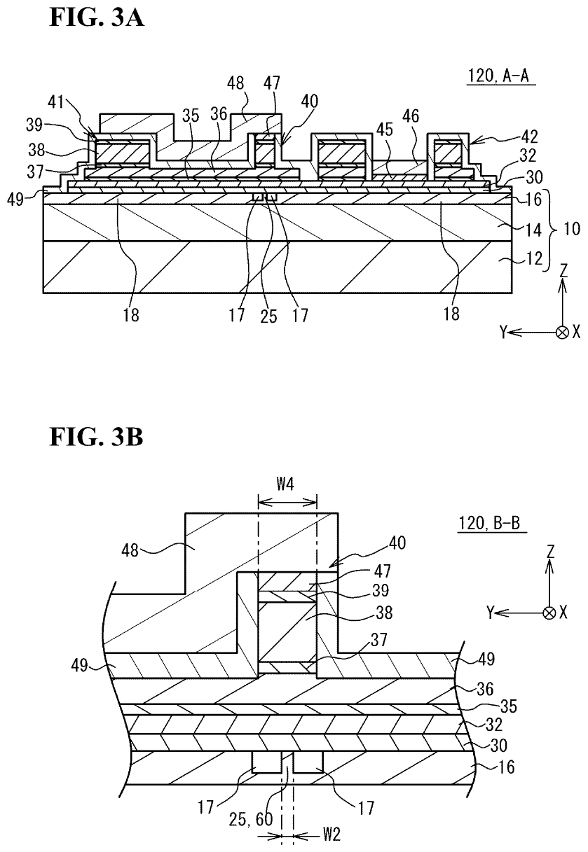

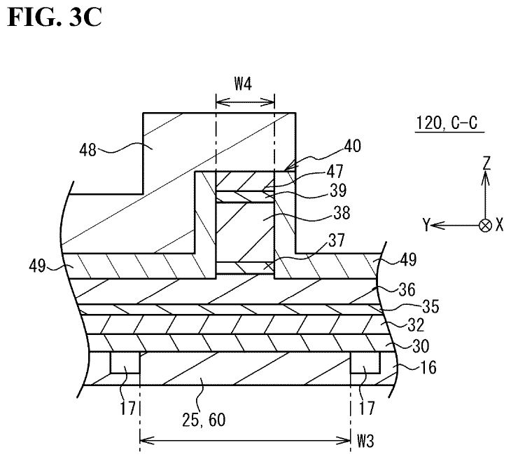

FIG. 2A is a plan view illustrating the SOA 120. FIG. 2B is a plan view illustrating the substrate 10 of the SOA 120, and the gain section 22 is removed from FIG. 2A. FIGS. 3A to 3C are cross-sectional views illustrating the SOA 120.

FIG. 3A illustrates a cross-section along line A-A of FIG. 2A. As illustrated in FIG. 3A, the substrate 10 is an SOI substrate, and includes a substrate 12, a box layer 14, and a silicon layer 16. The box layer 14 and the silicon layer 16 are sequentially stacked on one surface of the substrate 12. The substrate 12 is formed of, for example, silicon. The thickness of the substrate 12 is, for example, 350 μm. The box layer 14 is formed of, for example, silicon oxide (SiO₂). The thickness of the box layer 14 is, for example, 3 μm. The thickness of the silicon layer 16 is, for example, the 220 nm. The refractive index of the silicon layer 16 is 3.45. The refractive index of the box layer 14 and a cladding layer 49 described later is lower than the refractive index of the silicon layer 16 and is 1.45. These refractive indices are values for light having a wavelength of 1.55 μm.

The gain section 22 includes a mesa 40, a mesa 41, and a mesa 42. The mesa 42, the mesa 40, and the mesa 41 are arranged in this order in the Y-axis direction. The mesa 40, the mesa 41, and the mesa 42 protrude in the Z-axis direction. The mesa 40, the mesa 41, and the mesa 42 protrude in a direction away from the substrate 10 with reference to the upper surface of the silicon layer 16. In the cross-section of FIG. 3A, the mesa 42 is provided with a recessed portion that extends to cladding layer 32.

The gain section 22 includes a damage relaxation layer 30 (first semiconductor layer), the cladding layer 32 (first semiconductor layer), a light confinement layer 35, an active layer 36, a light confinement layer 37, a cladding layer 38 (second semiconductor layer), and a contact layer 39 (second semiconductor layer). The damage relaxation layer 30 is bonded to the upper surface of the silicon layer 16 and comes into directly contact with the upper surface of the silicon layer 16. The cladding layer 32, the light confinement layer 35, and the active layer 36 are stacked in this order on a surface of the damage relaxation layer 30 opposite to the silicon layer 16. The damage relaxation layer 30 and the cladding layer 32 extend below and between the mesa 40, the mesa 41 and the mesa 42. The damage relaxation layer 30 may not be provided. When the damage relaxation layer 30 is not provided, the cladding layer 32 is in direct contact with the upper surface of the silicon layer 16. A thin resin adhesive or an insulating film may be provided between the damage relaxation layer 30 and the upper surface of the silicon layer 16.

Each of the mesa 40, the mesa 41, and the mesa 42 includes the light confinement layer 37, the cladding layer 38, and the contact layer 39. The active layer 36 and the light confinement layer 35 are located below the mesa 40, the mesa 41, and the mesa 42, and extend between the mesa 40 and the mesa 41. The active layer 36 and the light confinement layer 35 are not provided between the mesa 40 and the mesa 42.

The cladding layer 49 is formed of, for example, SiO₂. The thickness of the cladding layer 49 is, for example, 1 μm. The cladding layer 49 covers the surfaces of the gain section 22 and the silicon layer 16. The cladding layer 49 covers the side surfaces of the mesa 40, the mesa 41, and the mesa 42, and covers the upper surfaces of the mesa 41 and the mesa 42. The cladding layer 49 covers a surface of the gain section 22 between the mesa 41 and the mesa 40 and a surface of the gain section 22 between the mesa 40 and the mesa 42. The cladding layer 49 has an opening at the top of the mesa 40 and an opening in the recessed portion of the mesa 42.

An electrode 45 is provided in the recessed portion of the mesa 42 and is in contact with the cladding layer 32. A wiring 46 is provided on the surface of the electrode 45 and is electrically connected to the cladding layer 32 and the electrode 45. An electrode 47 is in contact with the contact layer 39 of the mesa 40. A wiring 48 extends from the mesa 40 to the mesa 41 on the upper surface of the cladding layer 49. The wiring 48 is provided on the surface of the electrode 47 and is electrically connected to the contact layer 39 and the electrode 47. The electrode 45 is formed of, for example, an alloy (AuGeNi) of gold, germanium, and Ni. The electrode 47 is formed of, for example, a stacked structure (Ti/Pt/Au) of titanium, platinum, and gold. The wirings 46 and 48 are formed of a metal such as gold (Au) having a thickness of 3 μm, for example, and are electrically connected to an external device.

As illustrated in FIG. 2A, the gain section 22 is bonded to the silicon layer 16 of the substrate 10. The silicon layer 16 has the waveguide 25, a recessed portion 17, and a terrace 18. Two recessed portions 17 are grooves extending along the waveguide 25, and are provided on both sides of the waveguide 25 in two directions along the Y-axis. Each of the two recessed portions 17 is located between the waveguide 25 and the terrace 18. The terrace 18 is located outside the recessed portion 17 in the two directions along the Y-axis, and is a flat portion.

As illustrated in FIG. 3A, the upper surfaces of the waveguide 25 and the terrace 18 have the same height in the Z-axis direction with reference to the upper surface of the substrate 12. The height of the bottom surface of the recessed portion 17 is lower than the height of the upper surface of the terrace 18 or the height of the upper surface of the waveguide 25 with reference to the upper surface of the substrate 12. The recessed portion 17 extends from the upper surface of the silicon layer 16 toward the box layer 14. The recessed portion 17 may extend partway through the silicon layer 16 or may penetrate the silicon layer 16. The recessed portion 17 is filled with air.

The mesa 41 of the gain section 22 is located above one of two terraces 18. The mesa 42 is located above the other of two terraces 18. The mesa 40 is located above the waveguide 25. The damage relaxation layer 30 and the cladding layer 32 extend over a range wider than three mesas in the XY plane. The damage relaxation layer 30 and the cladding layer 32 have a tapered portion 50 and a tapered portion 52. The tapered portion 50 (second tapered portion) is located at the first end portion of the gain section 22 and protrudes from the first end portion toward the waveguide 25. The tapered portion 52 (second tapered portion) is located at the second end portion of the gain section 22 and protrudes from the second end portion in the X-axis direction. The tapered portion 50 and the tapered portion 52 become thinner as the tapered portion 50 and the tapered portion 52 are farther away from the gain section 22 along the X-axis. The tapered portion 50 functions as an input end of the gain section 22 and is a part of the input end. The tapered portion 52 functions as an output end of the gain section 22 and is a part of the output end. Light is input to the gain section 22 from the tapered portion 50 and is output from the tapered portion 52.

The mesa 40 is located between the tapered portion 50 and the tapered portion 52 in the X-axis direction and extends parallel to the X-axis. The mesa 40 has a tapered portion 54 and a tapered portion 56. The tapered portion 50, the tapered portion 54, the tapered portion 56, and the tapered portion 52 are arranged in the X-axis direction. The tapered portion 54 (first tapered portion) is located at one end portion of the mesa 40 along the X-axis and protrudes toward the tapered portion 50. The tapered portion 56 (first tapered portion) is located at the other end portion of the mesa 40 along the X-axis and protrudes in the X-axis direction. The tapered portion 54 and the tapered portion 56 become thinner as the tapered portion 54 and the tapered portion 56 are farther away from the mesa 40 along the X-axis. The tapered portion 54 functions as an input end of the mesa 40. The tapered portion 56 functions as an output end of the mesa 40.

The damage relaxation layer 30, the light confinement layer 35, and the light confinement layer 37 are formed of, for example, undoped gallium indium arsenide phosphide (i-GaInAsP). The thickness of the damage relaxation layer 30 is, for example, 200 nm. The thickness of the light confinement layer 35 and the light confinement layer 37 is, for example, 100 nm. The band gap wavelengths of the damage relaxation layer 30, the light confinement layer 35, and the light confinement layer 37 are, for example, 1.2 μm and are shorter than the wavelength of the emitted light of the gain section 20.

The cladding layer 32 is formed of, for example, n-type (first conductivity type) indium phosphide (n-InP). The thickness of the cladding layer 32 is, for example, 200 nm. The cladding layer 32 is doped with, for example, Si as an n-type dopant. The dopant concentration of the cladding layer 32 is, for example, 1×10¹⁹ cm⁻³. The cladding layer 38 is formed of, for example, p-type (second conductivity type) InP (p-InP). The thickness of the cladding layer 38 is, for example, 1500 nm. The contact layer 39 is formed of, for example, (p+)-type gallium indium arsenide ((p+)-GaInAs). The contact layer 39 is doped with, for example, zinc (Zn) as a p-type dopant. The dopant concentration of the cladding layer 38 is, for example, 1×10¹⁸ cm⁻³. The dopant concentration of the contact layer 39 is, for example, 1×10¹⁹ cm⁻³.

The active layer 36 has a multi quantum well (MQW) structure and includes a plurality of well layers and a plurality of barrier layers. The well layers and the barrier layers are alternately stacked. One well layer is formed of, for example, gallium indium arsenide phosphide (GaInAsP) having a thickness of 6 nm. One barrier layer is formed of, for example, GaInAsP having a thickness of 10 nm.

A p-type cladding layer 38, an i-type active layer 36, and an n-type cladding layer 32 are stacked to form a pin (positive-intrinsic-negative) junction. The mesa 40 functions as a current constriction structure. Current flows intensively through the mesa 40, and carriers are injected into the active layer 36. Stimulated emission occurs, and the light incident on the gain section 22 is amplified.

As illustrated in FIG. 2B, the waveguide 25 extends parallel to the X-axis. The waveguide 25 has a portion 58, a portion 59, a portion 60, a portion 61, and a portion 62. The portion 58, the portion 59, the portion 60, the portion 61, and the portion 62 are arranged in order along the X-axis direction.

The portion 58 has a portion overlapping the tapered portion 54 and the tapered portion 50 of the gain section 22 in a plan view, and a portion extending outside the gain section 22. The portion 62 has a portion overlapping the tapered portion 56 and the tapered portion 52 in a plan view, and a portion extending outside the gain section 22. Widths W1 of the portions 58 and 62 are constant. The width W1 is, for example, 0.5 μm.

The planar shape of the portion 59, the portion 60, and the portion 61 is a tapered shape. The portion 59 is connected to the portion 58 and the portion 60. The width of the portion 59 is larger as it is closer to the portion 58 and smaller as it is closer to the portion 60. The portion 60 is connected to the portion 59 and the portion 61. The width of the portion 60 is smaller as it is closer to the portion 59, and is larger as it is closer to the portion 61. A width W2 of the portion 60 at the position where the portion 60 is connected to the portion 59 is, for example, 0.2 μm. A width W3 of the portion 60 at the position where the portion 60 is connected to the portion 61 is, for example, 4.0 μm. The portion 61 is connected to the portion 60 and the portion 62. The width of the portion 61 is larger as it is closer to the portion 60, and is smaller as it is closer to the portion 62.

In each of the portion 59, the portion 60, and the portion 61, the width uniformly varies along the X-axis direction. That is, the rate of change of the width is constant in each portion.

A length L1 of the portion 59 is, for example, 50 μm. A length L2 of the portion 60 is, for example, 1000 μm. A length L3 of the portion 61 is, for example, 50 μm.

FIG. 3B is a cross-sectional view taken along line B-B of FIG. 2A, illustrating the connection position of the portions 60 and 59 of the waveguide 25. FIG. 3C is a cross-sectional view taken along line C-C of FIG. 2A, illustrating the connection position of the portions 60 and 61 of the waveguide 25. In FIGS. 3B and 3C, the mesa 40 and its vicinity are enlarged. In FIGS. 3B and 3C, the silicon layer 16 of the substrate 10 is illustrated, and the box layer 14 and the substrate 12 are omitted.

As illustrated in FIGS. 3B and 3C, a width of the mesa 40 in the Y-axis direction is defined as W4. A widths W4 is constant along the X-axis direction and are, for example, 2 μm. As illustrated in FIG. 3B, at the connection position of the portions 60 and 59, the width W2 of the waveguide 25 is smaller than the width W4 of the mesa 40. As illustrated in FIG. 3C, at the connection position of the portions 60 and 61, the width W3 of the waveguide 25 is larger than the width W4 of the mesa 40. The width of the portion 60 of the waveguide 25 varies uniformly and continuously along the X-axis direction. The width of the portion 60 is smaller as it is closer to the input end of the gain section 22, and is larger as it is closer to the output end of the gain section 22.

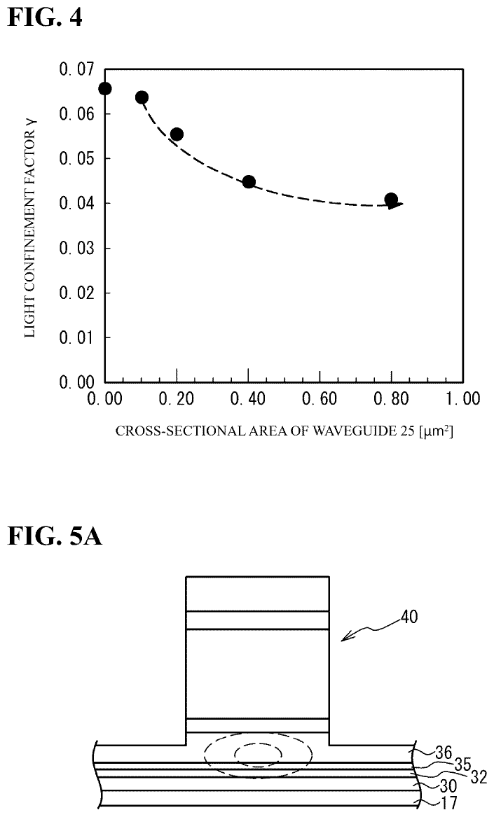

FIG. 4 is a diagram illustrating the calculation result of a light confinement factor. The horizontal axis represents the cross-sectional area of the waveguide 25. The vertical axis represents a light confinement factor γ to the active layer 36. The cross-sectional area of the waveguide 25 is the area of a cross section when the waveguide 25 is cut along a plane parallel to an YZ plane. The thickness of the waveguide 25 in the Z-axis direction is 0.2 μm. When the width of the waveguides 25 in the Y-axis direction is 0 μm to 5 μm, the cross-sectional area is 0 μm² to 1.00 μm². When the cross-sectional area is 0 μm², the waveguide 25 disappears, the two recessed portions 17 of the silicon layer 16 join at a position overlapping the mesa 40, and the two recessed portions 17 form one cavity below the mesa 40. The width W4 of the mesa 40 is 2 μm.

As illustrated in FIG. 4, the smaller the cross-sectional area of the waveguide 25, the higher the light confinement factor γ to the active layer 36. The larger the cross-sectional area, the smaller the light confinement factor γ. When the cross-sectional area of the waveguide 25 is 0 μm², the light confinement factor γ is 0.066 (6.6 %). When the cross-sectional area of 0.10 μm², the light confinement factor γ is higher than 6.0%. When the cross-sectional area is 0.20 μm², the light confinement factor γ is about 5.6%. When the cross-sectional area is 0.40 μm², the light confinement factor γ is about 4.5%. When the cross-sectional area is 0.08 μm², the light confinement factor γ is about 4.1%. When the cross-sectional area of the waveguide 25 is further increased, it is estimated that the light confinement factor γ is saturated at about 4.0%.

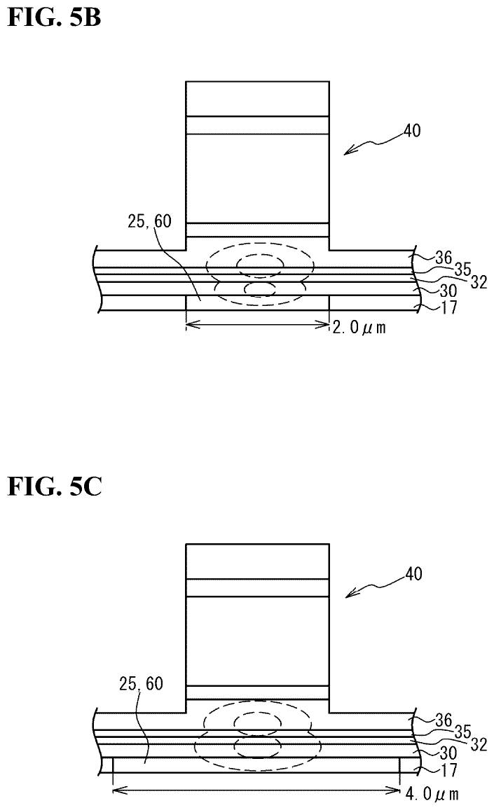

FIGS. 5A to 5C are schematic views illustrating light distribution, and illustrate cross sections including the mesa 40. The light distribution is illustrated by dashed lines. The light distribution is obtained by simulation calculation. An inner ellipse represents a portion where the light is intensively distributed. The light also spreads in the range of an outer ellipse. FIG. 5A illustrates an example in which the cross-sectional area and width of the waveguide 25 are zero. The recessed portion 17 is disposed below the mesa 40, and no silicon waveguide is provided below the mesa 40. The light confinement factor γ is 6.6%. The light is distributed mainly in an area of the active layer 36, the area being directly below the mesa 40.

FIG. 5B illustrates an example in which the waveguide 25 has a cross-sectional area of 0.40 μm² and a width of 2μm. Since the light confinement factor γ is reduced to 4.5%, the light is distributed in both the active layer 36 and the waveguide 25. FIG. 5C illustrates an example in which the waveguide 25 has a cross-sectional area of 0.80 μm² and a width of 4 μm. Since the light confinement factor γ is reduced to 4.1%, the light is further transferred to the waveguide 25. In the example of FIGS. 5A to 5C, the mode field width of the light is substantially constant. In the example of FIGS. 5A to 5C, a high-order transverse mode is not excited, and the light propagates through the gain section 22 in a single mode. The light is the single mode in both the waveguide 25 and the active layer 36. The loss of light in the coupling between the waveguide 25 and the gain section 22 is reduced.

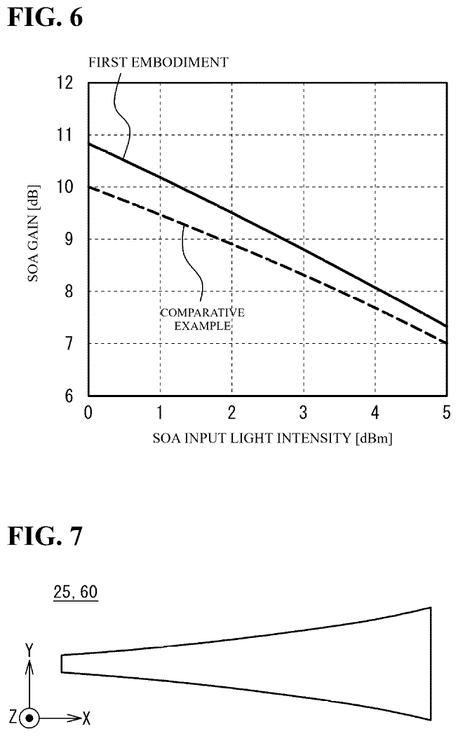

FIG. 6 is a diagram illustrating gain. The horizontal axis represents the intensity of light input to the SOA 120. The vertical axis represents the gain of the SOA 120. The solid line represents the calculation result of the gain in the first embodiment. The dashed line represents the calculation result of the gain in a comparative example. In the comparative example, the width of the waveguide 25 is constant and is 2.0 μm. In the first embodiment, the width of the waveguide 25 varies. The widths W2 and W3 are 0.5 μm and 4.0 μm, respectively. A current of 300 mA is input to the SOA 120. As illustrated in FIG. 6, the lower the intensity of the input light, the higher the gain. The gain of the first embodiment is higher than the gain of the comparative example at any value of the intensity. At a constant current, a higher gain is obtained in the first embodiment than in the comparative example. The power consumption of the SOA 120 can be reduced by, for example, about 20%.

### (Manufacturing Method)

An SOI wafer (substrate 10) and a III-V compound semiconductor wafer are used for manufacturing the semiconductor laser device 100. The recessed portion 17 is formed by dry etching the silicon layer 16 of the substrate 10. The portions that are not dry etched become the waveguide and the terrace 18. The width of the waveguide 25 can be controlled as illustrated in FIG. 2B in accordance with the shape of an etching mask.

For example, the contact layer 39, the cladding layer 38, the light confinement layer 37, the active layer 36, the light confinement layer 35, the cladding layer 32, and the damage relaxation layer 30 are epitaxially grown in this order on the upper surface of an (n+)-type InP wafer by organometallic vapor phase epitaxy (OMVPE) or the like. The wafer is diced to obtain small pieces for forming the gain section 22 and the gain section 20. The small pieces for forming the gain section 20 may be formed from a wafer different from the InP wafer from which the small pieces for forming the gain section 22 are obtained. The surfaces of the damage relaxation layer 30 and the silicon layer 16 are subjected to nitrogen (N₂) plasma treatment to activate the surfaces thereof. The activated surface is cleaned ultrasonically in water. The surface of the damage relaxation layer 30 and the upper surface of the silicon layer 16 are brought into contact with each other in the air at room temperature, and temporary bonding is performed. A H₂ junction is formed between the surfaces of the damage relaxation layer 30 and the silicon layer 16. After the temporary bonding, annealing is performed at 300° C. for two hours, for example, to remove moisture from the temporarily bonded interface and increase the bonding strength. A O₂ junction is formed between the surfaces of the damage relaxation layer 30 and the silicon layer 16. The gain section 20 is bonded on the waveguide 23. The gain section 22 is bonded on the waveguide 25.

For example, wet etching is performed using hydrochloric acid (HCl) as an etchant to remove the InP substrate from the gain section 20 and the gain section 22. Further, wet etching or the like is performed to form a mesa and a tapered portion in each of the gain section 20 and the gain section 22. The cladding layer 49 is formed by a plasma-enhanced CVD (PECVD) method or the like. An opening is formed in the cladding layer 49. The electrode 45 and the electrode 47 are provided in the opening by vacuum deposition and lift-off. The wiring 46 and the wiring 48 are provided by, for example, plating. The semiconductor laser device 100 is formed by dicing the substrate 10 in a wafer state.

According to the first embodiment, the gain section 22 of the SOA 120 is bonded to the waveguide 25 of the substrate 10. The cross-sectional area of the portion of the waveguide 25 that overlaps the gain section 22 varies. In the waveguide 25, a portion close to the input end of the gain section 22 has a smaller cross-sectional area, and a portion close to the output end of the gain section 22 has a larger cross-sectional area. The smaller the cross-sectional area of the waveguide 25, the higher the light confinement factor of the gain section 22 in the active layer 36. The larger the cross-sectional area of the waveguide 25, the lower the light confinement factor. Since the cross-sectional area of the waveguide 25 is small at a position close to the input end of the gain section 22, the light input from the input end (tapered portion 50) is confined in the active layer 36. The light is amplified in the gain section 22. The closer to the output end (tapered portion 52), the larger the cross-sectional area of the waveguide 25 and the lower the light confinement factor to the active layer 36. A part of the light is distributed in the waveguide 25. Thus, the gain is less likely to be saturated near the output end. As illustrated in FIG. 6, the gain of the SOA 120 is high. The power consumption of the SOA 120 can be reduced.

The mesa 40 of the gain section 22 is provided above the waveguide 25. The mode shape of the light is predominantly determined by the mesa 40. By providing the mesa 40, a higher-order transverse mode is less likely to occur, and the light propagates as a single mode. In the tapered portion 50, the single-mode light is transferred from the waveguide 25 to the gain section 22. In the tapered portion 52, the single-mode light is transferred from the gain section 22 to the waveguide 25. The light is in a single mode, so that the loss of light is reduced at each transfer.

In general, since light is amplified as the light propagates through the gain section 22, the intensity of light increases as it is closer to the output end of the gain section 22. When the intensity of light distributed in the active layer 36 is too large, the gain is reduced, and the light is not amplified any more. In the embodiment, the portion 60 of the waveguide 25 is located below the gain section 22, and the width of the portion 60 varies. The width of the portion of the waveguide 25 close to the input end of the gain section 22 is small, and the cross-sectional area of the waveguide 25 is small. The width of the portion of the waveguide 25 close to the output end of the gain section 22 is large, and the cross-sectional area of the waveguide 25 is large. When the cross-sectional area of the waveguide 25 is large, the intensity of light distributed in the waveguide 25 increases, and the intensity of light distributed in the active layer 36 of the gain section 22 decreases. The gain of the SOA 120 can be prevented from decreasing near the output end, and the gain can be prevented from being saturated.

The width W3 of the portion 60 of the waveguide 25 close to the output end is larger than the width W2 close to the input end. The width W3 is, for example, at least three times, at least four times, at least five times, at least ten times, or at least twenty times the width W2. The width W2 is, for example, 0.2 μm. The width W3 is, for example, 4.0 μm. The thickness of the waveguide 25 may vary in addition to the width. The waveguide 25 is thin near the input end, and the waveguide 25 is thick near the output end. The cross-sectional area varies.

As illustrated in FIG. 2A, the mesa 40 has the tapered portion 54 and the tapered portion 56. The tapered portion 54 functions as the input end of the mesa 40. The tapered portion 56 functions as the output end of the mesa 40. In the tapered portion 54, the light gradually transfers from the waveguide 25 to the active layer 36. At the tapered portion 56, the light transfers from the active layer 36 to the waveguide 25. The portion 60 of the waveguide 25 is located between the tapered portion 54 and the tapered portion 56. The width of the waveguide 25 is smaller as it is closer to the tapered portion 54 and larger as it is closer to the tapered portion 56. Thus, the closer to the tapered portion 56, the lower the light confinement factor in the active layer 36. Before reaching the tapered portion 56, the light also spreads out in the waveguide 25. The gain is not easily saturated.

As illustrated in FIGS. 3B and 3C, the mesa 40 has the width W4. Except for the tapered portion 54 and the tapered portion 56, the width of the mesa 40 is constant. The width of the mesa 40 determines the mode shape of the light. A high-order transverse mode is less likely to occur, and a single mode propagates through the mesa 40. In the optical coupling between the waveguide 25 and the mesa 40, a mode change is less likely to occur, and the loss of light is reduced.

The width W4 of the mesa 40 is, for example, 2 μm, and the width W4 is larger than the width W2 of the waveguide 25 and smaller than the width W3 of the waveguide 25. At a position close to the tapered portion 54, the mesa 40 is wider than the waveguide 25, and thus the light is transferred from the waveguide 25 to the active layer 36. The light can be amplified in the gain section 22. At a position close to the tapered portion 56, the waveguide 25 is wider than the mesa 40. Thus, the light is also distributed in the waveguide 25. The gain is not easily saturated.

The gain section 22 includes the damage relaxation layer 30, the cladding layer 32, the active layer 36, the cladding layer 38, and the contact layer 39. The n-type cladding layer 32, the i-type active layer 36, and the p-type cladding layer 38 form a pin junction. The mesa 40 can constrict the current and intensively inject carriers into the active layer 36 under the mesa 40. The light can be efficiently amplified. The amplified light is also distributed in the wide waveguide 25. The saturation of the gain can be prevented.

The damage relaxation layer 30 and the cladding layer 32 have the tapered portion 50 and the tapered portion 52. The tapered portion 50 functions as the input end of the gain section 22. The tapered portion 52 functions as the output end of the gain section 22. The portion 60 of the waveguide 25 has a width that decreases as it is closer to the tapered portion 50 and increases as it is closer to the tapered portion 52. The saturation of the gain can be prevented.

The silicon layer 16 has the recessed portion 17. The recessed portions 17 are located on both sides of the waveguide and extend along the waveguide. As illustrated in FIG. 2B, the recessed portion 17 extends along the waveguide 25 of which width varies. The inside of the recessed portion 17 is filled with air. The refractive index of air is lower than the refractive index of silicon. The light can be concentrated around the silicon waveguide 25 to prevent the spreading of the mode. The light is transferred between the waveguide 25 and the active layer 36 on the waveguide 25.

As illustrated in FIG. 2B, the width of the waveguide 25 varies linearly and continuously along the X-axis direction. In other words, the side surface of the waveguide 25 is a straight line in a plan view. As illustrated in FIG. 4, the light confinement factor decreases in accordance with the linear spreading of the width. The saturation of the gain can be prevented.

### Second Embodiment

FIG. 7 is a plan view illustrating the portion 60 of the waveguide 25 according to a second embodiment. The description of the same configuration as that of the first embodiment will be omitted. The width of the portion 60 of the waveguide 25 varies non-linearly and continuously, for example, according to a parabola. The side surface of the waveguide 25 has a parabolic shape in a plan view.

According to the second embodiment, the width of the waveguide 25 varies, and thus the light confinement factor in the active layer 36 varies. The wider the width, the lower the light confinement factor. The width increases rapidly toward the output side, and the light confinement factor also varies steeply. The light is easily transferred to the waveguide 25, and the saturation of the gain can be prevented.

### Third Embodiment

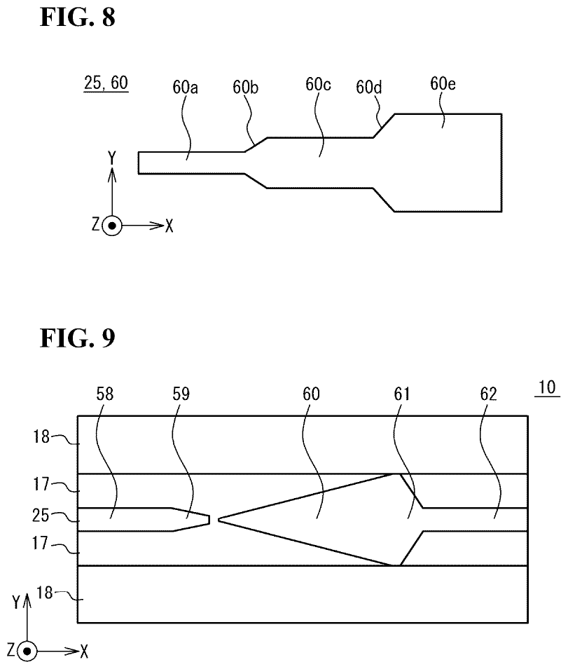

FIG. 8 is a plan view illustrating the portion 60 of the waveguide 25 according to a third embodiment. The description of the same configuration as that of the first embodiment or the second embodiment will be omitted. The width of the portion 60 of the waveguide 25 varies non-uniformly and discontinuously. The portion 60 of the waveguide 25 is a multi-stage tapered shape.

The portion 60 includes a portion 60a, a portion 60b, a portion 60c, a portion 60d, and a portion 60e. The portion 60a to the portion 60e are arranged in this order along the X-axis direction. The portion 60a, the portion 60c, and the portion 60e have a linear shape. The width of the portion 60c is larger than the width of the portion 60a and smaller than the width of the portion 60e. The width of the portion 60e is larger than the width of the portion 60a and the width of the portion 60c. The portion 60b is connected to the portion 60a and the portion 60c, and has a tapered shape. The width of the portion 60b is smaller as it is closer to the portion 60a, and is larger as it is closer to the portion 60c. The portion 60d is connected to the portion 60c and the portion 60e, and has a tapered shape. The width of the portion 60d is smaller as it is closer to the portion 60c, and is larger as it is closer to the portion 60e. The widths of the tapered portions 60b and 60d vary linearly and continuously.

According to the third embodiment, the width of the waveguide 25 varies, and thus the light confinement factor in the active layer 36 varies. The wider the width, the lower the light confinement factor. The width increases rapidly toward the output side. The light confinement factor also varies steeply. The light is easily transferred to the waveguide 25, and the saturation of the gain can be prevented.

The two portions 60b and 60d of the waveguide 25 may have a tapered shape, or one portion or three or more portions may have a tapered shape. The width of a portion of the waveguide 25 may vary in a parabolic shape as illustrated in FIG. 7.

### Fourth Embodiment

FIG. 9 is a plan view illustrating the substrate 10 of the SOA according to a fourth embodiment. The description of the same configuration as that of the first embodiment to the third embodiment will be omitted. The width of the portion 60 of the waveguide 25 varies. The portion 60 is separated from portion 59. The recessed portion 17 is disposed between the portion 60 and the portion 59. The portion 60 widens towards the portion 61 and is connected to the terrace 18. The recessed portion 17 is blocked by the portion 60 in the X-axis direction.

According to the fourth embodiment, the width of the waveguide 25 varies from 0 μm to the size at which the waveguide 25 is connected to the terrace 18. Since the light confinement factor in the active layer 36 decreases as the width of the waveguide 25 increases, the gain saturation can be prevented.

The light is transferred to the active layer 36 near the tapered portion 54 of the gain section 22. The portion 59 and the portion 60 of the waveguide 25 are located rearward of the tapered portion 54 in the X-axis direction. Even with air (recessed portion 17) under the mesa 40, the light is confined, so that the loss is reduced. At a position close to the tapered portion 56, the portion 60 is connected to the terrace 18. Since the mode shape is determined by the mesa 40, a high-order transverse mode is less likely to occur.

Although the embodiments of the present disclosure have been described in detail, the present disclosure is not limited to the specific embodiments, and various modifications and changes can be made within the scope of the gist of the present disclosure described in the claims.

What is claimed is:

1. A semiconductor optical amplifier comprising:
a substrate including a silicon layer; and
a gain section formed of a III-V compound semiconductor and having an optical gain, the gain section being bonded to the silicon layer,
wherein the silicon layer has a waveguide,
wherein the gain section has a mesa at a position overlapping the waveguide,
wherein the mesa protrudes in a direction away from the substrate and is located over the waveguide, and
wherein, in a portion of the waveguide overlapping the mesa, a portion of the waveguide close to an input end of the gain section has a smaller cross-sectional area, and a portion of the waveguide close to an output end of the gain section has a larger cross-sectional area.

2. The semiconductor optical amplifier according to claim 1,
wherein, in the portion of the waveguide overlapping the mesa, the portion of the waveguide close to the input end of the gain section has a smaller width, and the portion of the waveguide close to the output end of the gain section has a larger width.

3. The semiconductor optical amplifier according to claim 1,
wherein the width of the portion of the waveguide close to the output end of the gain section is four or more times as large as the width of the portion of the waveguide close to the input end of the gain section.

4. The semiconductor optical amplifier according to claim 1
wherein the mesa has a first tapered portion at each of an end portion close to the input end and an end portion close to the output end, and
wherein, in a portion of the waveguide located between two first tapered portions, a portion of the waveguide close to the input end of the gain section has a larger cross-sectional area, and a portion of the waveguide close to the output end of the gain section has a smaller cross-sectional area.

5. The semiconductor optical amplifier according to claim 4,
wherein the mesa has a constant width along an extending direction of the waveguide between the two first tapered portions.

6. The semiconductor optical amplifier according to claim 5,
wherein the mesa has a width larger than the width of the portion of the waveguide close to the input end of the gain section and smaller than the width of the portion of the waveguide close to the output end of the gain section.

7. The semiconductor optical amplifier of claim 1,
wherein the gain section includes a first semiconductor layer, an active layer, and a second semiconductor layer,
wherein the first semiconductor layer is bonded to the substrate and has a first conductivity type,
wherein the active layer and the second semiconductor layer are sequentially stacked over the first semiconductor layer, and
wherein the second semiconductor layer forms the mesa and has a second conductivity type.

8. The semiconductor optical amplifier according to claim 7,
wherein the first semiconductor layer has two second tapered portions,
wherein one of the two second tapered portions forms a part of the input end,
wherein another one of the two second tapered portions forms a part of the output end,
wherein the mesa is located in a portion located between the two second tapered portions, and
wherein, in the portion located between the two second tapered portions, a portion of the waveguide close to the input end of the gain section has a smaller cross-sectional area, and a portion of the waveguide close to the output end of the gain section has a larger cross-sectional area.

9. The semiconductor optical amplifier of claim 1, wherein the silicon layer has a recessed portion, and wherein the recessed portion is located on each of two sides of the waveguide.

10. The semiconductor optical amplifier according to claim 1,
wherein the waveguide has a width that varies continuously or discontinuously along the extending direction of the waveguide.
